(19) United States
(12) Patent Application Publication
(10) Pub. No.: US 2026/0082940 A1
(43) Pub. Date: Mar. 19, 2026

(54) NANOTWIN COPPER PLATING FOR MULTI-LAYERED LEADFRAMES

(71) Applicant: TEXAS INSTRUMENTS INCORPORATED, DALLAS, TX (US)

(72) Inventors: Jeffrey S. SOLAS, ILOILO CITY (PH); Jomari AUSTRIA, MABALACAT (PH); Ray Fredric DE ASIS, MABALACAT (PH); Jose Arvin M. PLOMANTES, DAGUPAN (PH)

(21) Appl. No.: 18/890,117

(22) Filed: Sep. 19, 2024

(51) Int. Cl. H01L 23/495; H01L 21/48; H01L 21/56; H01L 23/00

(52) U.S. Cl. CPC H10W 70/457; H10W 70/041; H10W 70/421; H10W 70/451; H10W 74/016; H10W 72/075; H10W 72/551; H10W 72/5525; H10W 74/00; H10W 90/756

(57) ABSTRACT

A described example includes a method for fabricating an integrated circuit (IC) device. The method can include forming a mask on a surface of a multi-layer substrate, in which the multi-layer substrate includes at least one leadframe having spaced apart regions of copper distributed across and extending from the surface into at least one layer of the multi-layer substrate. The method can also include forming nanotwin copper bond pads on the surface of the multi-layer substrate over a respective region of the regions of copper. The method can also include removing the mask and forming a layer of an insulating material over the surface of the multi-layer substrate and around the nanotwin copper bond pad.

### TECHNICAL FIELD

This description relates generally to integrated circuits and fabrication thereof, and more particularly, to nanotwin copper plating for multi-layered leadframes.

### BACKGROUND

Integrated circuit (IC) packages have long been implemented in computer devices for providing increasingly compact circuits in computer products. Copper-to-copper bonding has been gaining traction due to the potentially significant cost savings. Other bonding approaches include ultrasonic bonding and use of a patterned capillary tip.

### SUMMARY

One example includes a method for fabricating an integrated circuit (IC) device. The method can include forming a mask on a surface of a multi-layer substrate, in which the multi-layer substrate includes at least one leadframe having spaced apart regions of copper distributed across and extending from the surface into at least one layer of the multi-layer substrate. The method can also include forming nanotwin copper bond pads on the surface of the multi-layer substrate over a respective region of the regions of copper. The method can also include removing the mask and forming a layer of an insulating material over the surface of the multi-layer substrate and around the nanotwin copper bond pad.

Another example described herein relates to an apparatus. For example, the apparatus can be a leadframe or a packaged integrated circuit device. The apparatus includes a multi-layer leadframe that includes a first layer and a second layer. The first layer includes spaced apart regions of electrically conductive material, defining respective vias, distributed across and extending from a first surface of the first layer of the leadframe into at least the first layer of the leadframe. The first layer also includes a first volume of an insulating material surrounding each of the respective terminals in the at least first layer of the leadframe. The second layer is over the first surface of the first layer. The second layer includes a nanotwin copper bond pad coupled to a respective one of the terminals and extending outwardly from the first surface of the first layer to terminate in a second surface of the leadframe. The second layer also includes a second volume of the insulating material surrounding the nanotwin copper bond pad in the second layer of the leadframe.

Another example described herein relates to a packaged integrated circuit device. The packaged integrated circuit includes a multi-layer substrate, a die, bond wires, and a mold compound. The multi-layer substrate includes a first layer and a second layer. The first layer includes a die pad and a plurality of nanotwin copper bond pads arranged and distributed about the die pad in the first layer of the multi-layer substrate. Each of the nanotwin copper bond pads has sidewalls surrounded by an electrically insulating material in the first layer of the multi-layer substrate. The second layer includes a plurality of spaced apart regions of electrically conductive material, defining respective terminals, which are distributed across the second layer of the multilayer substrate. Each of the respective terminals is coupled to a respective nanotwin copper bond pad, and each of the respective terminals extends into and is surrounded by an insulating material in the second layer of the multi-layer substrate. The die is on a surface of the die pad, in which the die includes a plurality of die bond pads on the surface thereof that is spaced apart from the surface of the die pad. The bond wires are coupled between each of the die bond pads and respective nanotwin copper bond pads. The mold compound is over the die, the bond wires and at least a portion of the multi-layer substrate.

### BRIEF DESCRIPTION OF THE DRAWINGS

FIG. 1 is a diagram illustrating an example integrated circuit device.

FIG. 2 is a flow diagram illustrating an example method for forming an IC device.

FIGS. 3-11 are examples of part of an IC device at different stages of the fabrication process.

FIG. 12 is a bar chart showing shear strength for bond wires bonded to different samples of nanotwin copper pads.

### DETAILED DESCRIPTION

This description relates generally to a leadframe apparatus, a packaged integrated circuit (IC) that includes the leadframe apparatus and to a method of fabrication.

As an example, a multi-layer leadframe includes a first layer and a second layer formed over the first layer (e.g., the second layer defines a top layer of the leadframe. The first layer includes spaced apart regions of electrically conductive material distributed across and extending from a first surface of the first layer of the leadframe into at least the first layer of the leadframe. The conductive regions can define respective vias or other conductive routing features for the leadframe, such as for routing signals through the layers of the leadframe. An electrically insulating material can surround each of the respective vias in the first layer of the leadframe. The second layer includes one or more nanotwin copper bond pads, each coupled to a respective one of the vias and extending outwardly from the first surface of the first layer. For example, the nanotwin copper bond pads can be formed on the respective vias in an electroplating process, which can be implemented through a patterned mask over the first surface to provide the nanotwin copper bond pads a columnar configuration. The second layer can also include another volume of the insulating material surrounding the nanotwin copper bond pad(s) in the second layer of the leadframe.

As a further example, a packaged IC device can be formed with the leadframe. For example, the packaged IC device includes a semiconductor die on a die pad of leadframe. The semiconductor die can include active circuitry formed therein and an arrangement of electrically conductive die bond pads on a surface of the die spaced apart from the die pad. The die bond pads can be coupled to the active circuitry through respective vias or other electrical connections. A bond wire (e.g., copper) can be coupled between pairs of the nanotwin copper bond pad and the electrically conductive bond pad of the die to provide a copper-to-copper bond between the bond wire and the nanotwin copper bond pad. A mold compound can extend over (e.g., encapsulate) the die, the bond wire, and at least a portion of the leadframe.

The nanotwin copper bond pads can be formed on the leadframe at lower temperature compared to other types of bond pads and exhibit improved bonding performance compared to other leadframes. The nanotwin copper bond pads also enable direct copper-to-copper connections using copper bond wires, which can improve adhesion and at lower cost compared to many existing approaches.

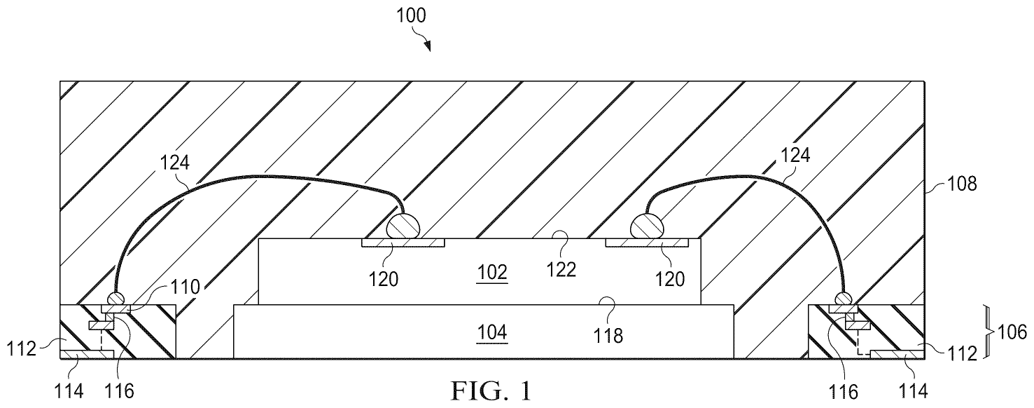

FIG. 1 depicts an example of an IC device 100. The IC device 100 is demonstrated in the example of FIG. 1 in a cross-sectional view to show relative locations of respective layers. The IC device 100 is demonstrated by way of example and is not intended to be shown to scale.

In the example of FIG. 1, the IC device 100 is a packaged IC device that includes an IC die 102 on a die pad 104 of a multi-layer substrate 106 and covered with a mold compound 108. The IC device 100 can be implemented according to a variety of different packaging types, including leaded and leadless packaging types.

In the example of FIG. 1, the multi-layer substrate 106 defines a leadframe that includes a number of two or more layers having respective electrically conductive regions (e.g., also referred to as vias or conductive routing features) for routing signals through the leadframe to leadframe terminals 114. For example, a first (e.g., top) layer includes the die pad 104 and a plurality of instances of the nanotwin copper bond pad 110 arranged and distributed about the die pad. Each of the nanotwin copper bond pads 110 has sidewalls surrounded by an electrically insulating material 112 in the first layer of the multi-layer substrate. The insulating material 112 within the multi-layer substrate 106 can be implemented as a build-up film material, a prepreg material, or an epoxy material. A next (e.g., second) layer of the multi-layer substrate 106 includes a plurality of spaced apart regions of electrically conductive material (e.g., copper) that define respective vias 116. The vias 116 can be distributed across the second layer of the multi-layer substrate at locations aligned with and coupled to a respective nanotwin copper bond pad 110. As shown, each of the respective conductive routing features 116 extends through the second layer of the multi-layer substrate and can be routed within one or more layers (schematically shown by dashed lines) to couple the bond pads 110 with respective leadframe terminals 114. Each of the vias 116 surrounded by additional insulating material 112 within respective layers of the multilayer substrate 106. The vias 116 and any additional metal routing within the layers between the bond pads 110 and the leadframe terminals 114 operate as redistribution layers of the multi-layer substrate 106.

The die 102 can be mounted to a surface 118 of the die pad 104 by a die attach material (not shown), such as an epoxy or solder. The die 102 includes a plurality of die bond pads 120 on a surface 122 thereof that is spaced apart from the surface of the die pad 104. The IC device 100 also includes bond wires 124 coupled between each of the die bond pads 120 and respective nanotwin copper bond pads 110. For example, the bond wires 124 are copper bond wires and are attached to the nanotwin copper bond pads 110 to provide copper-to-copper bonds between the respective bond wires and bond pads. The mold compound 108 can cover the die 102, the bond wires 124 and at least a portion of the multi-layer substrate 106 to define the packaged IC device 100.

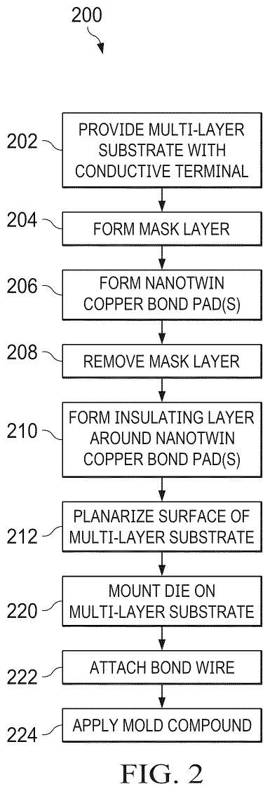

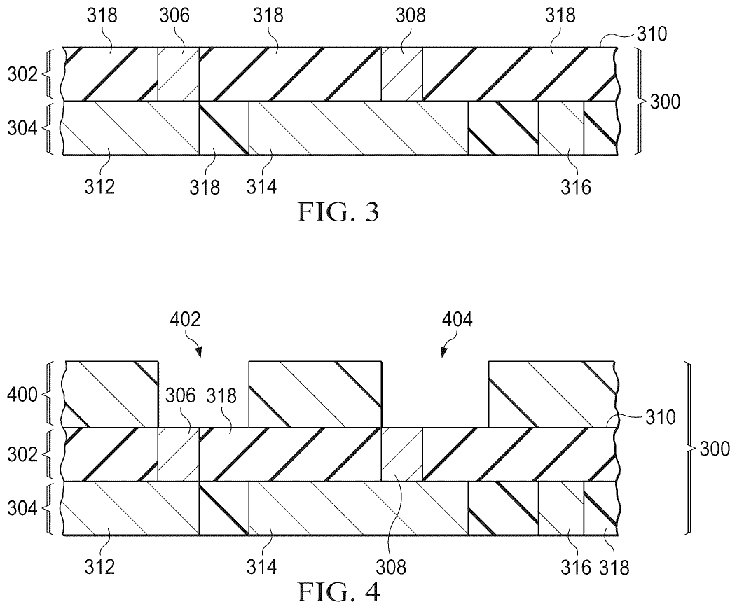

FIG. 2 is a flow diagram illustrating an example method 200 for forming an IC device, such as the IC device 100 of FIG. 1. Accordingly, the description of FIG. 2 refers to certain aspects of FIG. 1. For additional context, the method 200 of FIG. 2 will be described with respect to FIGS. 3-10, which are cross-sectional views depicting examples of part of the IC device 100 at different stages of the fabrication method 200. While the method 200 of FIG. 2 is shown and described as a sequence of steps or actions, the method 200 is not limited by the illustrated order, as some aspects could occur in different orders and/or concurrently with other aspects from that shown and described herein. Moreover, not all illustrated features may be required to implement the method 200.

The method 200 begins at 202, in which a multi-layer substrate having one or more conductive regions is provided. For example, as shown in FIG. 3, a multi-layer substrate 300 includes a plurality of layers 302 and 304. The multi-layer substrate 300 illustrates a useful example for the multi-layer substrate 106 in FIG. 1. In the example of FIG. 3, each of the layers 302 and 304 includes one or more conductive regions (e.g., vias or other conductive routing features). For example, the layer 302 includes conductive vias 306 and 308 extending from a first surface 310 of the multi-layer substrate 300 into the first layer of the leadframe. The layer 304 also includes an arrangement of conductive regions 312, 314, and 316, which can be implemented as vias or leadframe terminals depending on whether the layer 304 is a bottom or intermediate layer. The via 306 is coupled to and extends from the conductive regions 312 and the via 308 is coupled to and extends from the conductive regions 314. Each layer 302 and 304 of the multi-layer substrate 300 also includes a volume of an insulating material 318 surrounding each of the respective conductive regions 306, 308, 312, 314, and 316.

While the example of FIG. 3 includes two layers 302 and 304, at the illustrated stage of fabrication, the substrate 300 may include one layer or more than two layers. Thus, the layer 304 can define a bottom layer in which the conductive regions 312, 314, and 316 define leadframe terminals (e.g., terminals 114). Alternatively, the layer 304 can be an intermediate layer in which the conductive regions 312, 314, and 316 define respective vias of the intermediate layer.

As a further example, the multi-layer substrate 300 is a multi-layer leadframe substrate and part of the method 200 (e.g., 202 through 210) includes fabrication of the multi-layer leadframe substrate, which can be fabricated according to a multi-layer substrate fabrication technology, such as a routable lead frame (RLF) or embedded trace substrate (ETS) process, among others. For example, RLF is a multilayer substrate that includes a plurality (at least two) of stacked layers, in which each layer is pre-configured with metal plating, such as copper plating or interconnects, to provide electrical connections for routing electrical signals through respective layers of the substrate. RLF package substrates can have single-or multi-die configurations, both lateral and vertically stacked, which can include dielectric and metal layers (e.g., patterned metal) and include a number of vias extending between and/or through two or more of the layers thereof.

As another example, ETS is a multilayer package substrate that includes trace conductor layers that are spaced by prepreg laminated layers. The prepreg layers are dielectric material. Vias (e.g., conductive vias) are formed through the prepreg layers between multiple layers of trace conductors and couple the trace conductor layers. Additionally, the ETS can be used as a package substrate with multiple trace layers, and one or more passive components mounted to the ETS. A mold compound can cover the ETS, a semiconductor die mounted to the ETS and a passive component. A recess can be opened extending into the ETS from a device side surface to expose trace conductors at a trace level beneath the device side surface, and the passive component is mounted in the recess in the ETS.

At 204, the method includes forming a mask on a surface of a multi-layer substrate. For example, as shown in FIG. 4, a patterned mask 400 of a photoresist material (e.g., a photolithographic mask) is formed over the surface 310 of the layer 302 to provide openings 402 and 404 at locations overlying the respective conductive regions 306 and 308. In some examples, the openings 402 and 404 expose respective surfaces of the conductive regions 306 and 308 as well as the surface of adjacent parts of the layer 302. Each of the openings 402 and 404 has a cross-sectional configuration (e.g., along a virtual plane extending through the patterned mask parallel to the surface 310) according to the configuration of respective bond pad to be formed in a subsequent layer, as described herein.

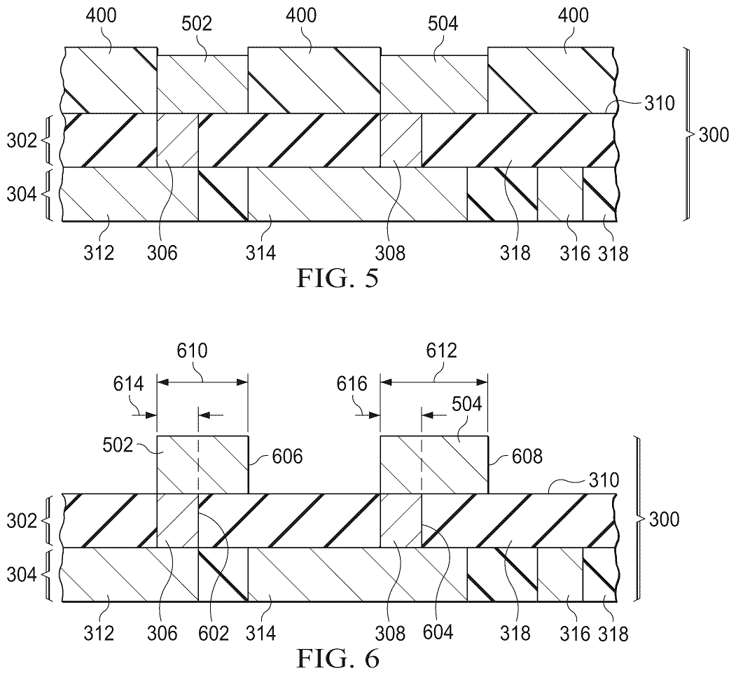

At 206, the method 200 includes forming one or more nanotwin copper bond pads on exposed portions of the surface of the multi-layer substrate through the openings in the mask layer (formed at 204). For example, as shown in FIG. 5, nanotwin copper (ntCu) bond pads 502 and 504 are formed within the openings 402 and 404 of the mask layer 400 over the respective region of the regions of conductive material 306 and 308, respectively. As an example, the nanotwin copper bond pads are formed by an electroplating process. The nanotwin copper bond pads 502 and 504 can be formed according to other nanotwinning methods, such as magnetron sputtering deposition, chemical vapor deposition, electro-deposition, or hybrid physical-chemical vapor deposition. The nanotwin copper bond pads thus can have a copper grain that includes a crystal lattice structure that has Miller indices of 111.

As a further example, the nanotwin copper bond pads 502 and 504 are formed through the pulsed plating process. For example, the current is pulsed at a frequency from about 5 Hz to about 10 Hz and a current magnitude ranging from about 40 A and a current less than 1 A. The pulsed current can have a duty cycle of about 25% or more in some examples. The pulsed plating process can further include immersing the leadframe substrate (e.g., one or more leadframes) 300 in a solution with a copper concentration ranging from about 30 grams per liter (g/L) to about 60 g/L, such as a copper concentration about 32 or about 55 g/L. It is understood that in other examples different concentrations can be implemented. In a first example where a 25% duty cycle is used and the solution has a copper concentration of 32 g/L, the pulsed plating can be applied for about 20-25 minutes to form a bond pad that is about 10 μm thick. Thus, the pulsed plate rate in the first example is about 0.45 μm per minute (μm/min). In a second example where the 25% duty cycle is used, and the solution has a copper concentration of 55 g/L, the pulsed plating can be applied for about 10.00 minutes to form a bond pad that is about 10 μm thick. Thus, the pulsed plate rate in the second example is about 1.0 μm/min. Other pulsed plate rates can be used in other examples.

At 208, the method 200 includes removing the mask layer. For example, as shown in FIG. 6, the patterned mask 400 can be removed so that the nanotwin copper bond pads 502 and 504 remain, in which the nanotwin copper bond pads are coupled to the conduction regions 306 and 308 at the surface 310 of the layer 302. As shown in FIG. 6, responsive to removing the mask layer (at 208), each of the nanotwin copper bond pads 502 and 506 is provided a columnar sidewall shape (e.g., defining a columnar nanotwin copper bond pad) extending outwardly a distance from the surface 310 to define a thickness of the respective bond pads. Further, each of the conductive regions 306 and 308 includes a sidewall 602 and 604 having a respective outer periphery at the surface 310 (e.g., defining a juncture between the layers that is surrounded by the insulating material). Similarly, each of the nanotwin copper bond pads 502 and 504 includes a columnar sidewall 606 and 608 having a respective outer periphery that is spaced outwardly in a direction orthogonal to the columnar sidewall beyond the outer periphery of the respective via to which it is coupled and over an adjacent portion of the insulating material of the second layer. Thus, each of the each of the nanotwin copper bond pads 502 and 504 can have a cross-sectional dimension (e.g., a width or diameter) 610 and 612 that is greater than a cross-sectional dimension (e.g., a width or diameter) 614 and 616 of the respective conductive regions 306 and 308.

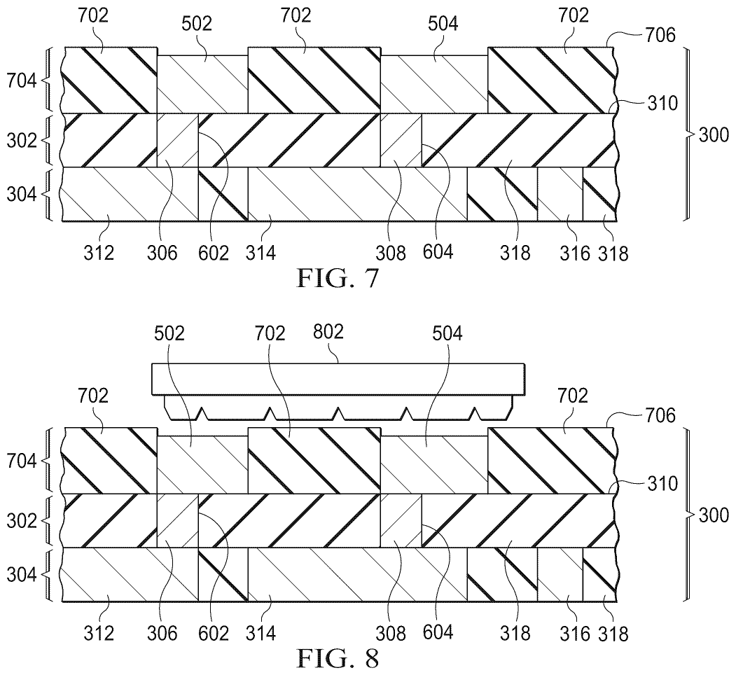

At 210, the method 200 includes forming a layer of an insulating material over the surface of the multi-layer substrate and around each of the bond pads. For example, as shown in FIG. 7, an insulating material 702 is provided on the surface 310 around the respective nanotwin copper bond pads 502 and 504 to define another layer 704 of the multi-layer substrate 300. Thus, in the example of FIG. 7, the layer 704 of the multi-layer substrate 300 includes the insulating material 702 and nanotwin copper bond pads 502 and 504. The insulating material 702 can be the same or different material than the insulating material 318 of one or more other layers 302 and 304. The insulating material 702 can be a build-up film such as Ajinomoto Build-up Film (ABF) dielectric materials, a prepreg material (e.g., a fiber weave or cloth of glass fibers, pre-impregnated with a bonding agent), or an epoxy material (e.g., a mold compound epoxy). For example, ABF is commercially available from Ajinomoto Co., Inc. and is known to comprise an epoxy resin together with a phenolic hardener.

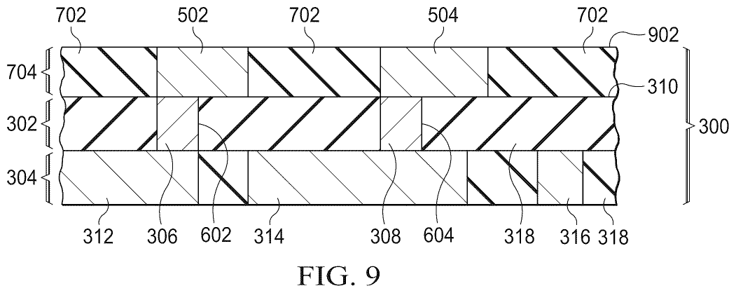

In some examples, as shown in FIG. 7, a surface 706 of the layer 704, which defines a top surface thereof that is spaced apart from the surface 310 of the layer 302, may not be planar (e.g., the surface of the nanotwin copper bond pads 502 and 504 is not coplanar with the surface of the insulating material 702). Additionally, or alternatively, some the insulating material applied at 210 can be present on the bond pad(s). Accordingly, at 212, the method 200 includes planarizing the surface (e.g., top) surface of the multilayer substrate. For example, as shown schematically at 802 in FIG. 8, the surface 706 of the insulating material 702 and the nanotwin copper pads 502 and 504 can be planarized, such as through a chemical mechanical polishing (CMP) process. For example, CMP 802 uses an abrasive and corrosive chemical slurry (e.g., a colloid) in combination with a polishing pad to remove material and provide the multi-layer substrate 300 a flat or planar surface 902 and to remove insulating material from the nanotwin copper pads 502 and 504, such as shown in FIG. 9. Other planarization processes can be used in other examples to provide the multilayer substrate 300 with the planar surface 902.

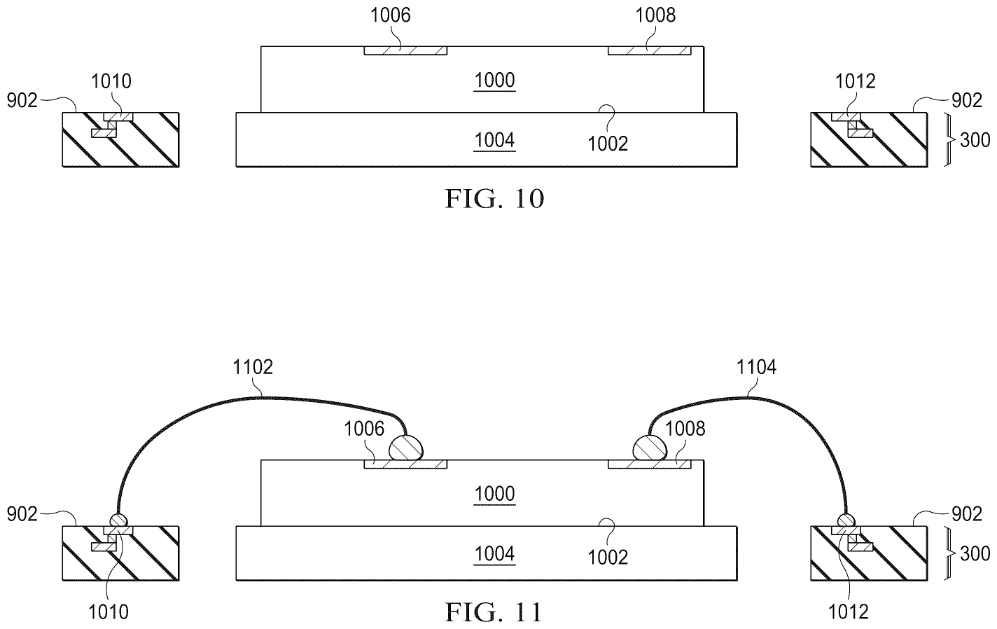

At 220, the method 100 includes mounting a die on the multi-layer substrate. For example, FIG. 10 illustrates a die 1000 (e.g., the die 102) mounted to a surface 1002 of a die pad 1004, which constitutes part of the multi-layer substrate (e.g.,), such as by a die attach material (not shown), such as an epoxy or solder material. The die 1000 includes a plurality of die bond pads 1006 and 1008 on the surface 1002 of the die. In the example of FIG. 10, the multi-layer substrate 300 is a multi-layer leadframe substrate that includes nanotwin copper bond pads 1010 and 1012, each of which can be an instance of the nanotwin copper bond pads 110, 502, or 504 described herein.

At 222, the method includes attaching a bond wire to the nanotwin copper bond pad. For example, FIG. 11 illustrates bond wires 1102 and 1104, which can be copper bond wires. The bond wire 1102 has a first end coupled to the nanotwin copper bond pad 1010 and a second end coupled to the die bond pad 1006. The bond wire 1104 has a first end coupled to the nanotwin copper bond pad 1012 and a second end coupled to the die bond pad 1008. In an example, the couplings between the first end of the bond wires 1102 and 1104 (e.g., bond wires 124) and the respective nanotwin copper bond pads 1010 and 1012 provide copper-to-copper bonds between the bond wire and the bond pads. As an example, the copper-to-copper bonds can be formed through an ultrasonic bonding process (e.g., also referred to as wedge bonding), which can be implemented at a lower temperature and achieve improved bonding than many existing wire bonding technologies. The second end of the bond wires 1102 and 1104 can be coupled to die bond pads 1006 and 1008 using the same or a different wire bonding process. Other wire bonding processes can be used to implement the wire bonding at 222 (e.g., thermo-compression bonding or ball bonding).

At 224, the method includes applying a mold compound over the die, the bond wire, and at least a portion of the multi-layer substrate to provide a packaged IC device. For example, FIG. 1 illustrates a packaged IC device that includes mold compound 108 over the die 102, the bond wires 124 and at least a portion of the multi-layer substrate 106 to define the packaged IC device 100.

In one example, the method 200 can be implemented to form a plurality of packaged IC devices 100 on a leadframe sheet that includes a plurality of interconnected multi-layer leadframes (e.g., instances of the multi-layer leadframe substrate 106, 300). Each packaged IC device can thus be singulated from the leadframe sheet as part of a singulation process to provide respective individual IC devices 100. In another example, the method 200 can be implemented to form a discrete (e.g., single) packaged IC device from a multi-layer leadframe, which has already been singulated from a leadframe sheet having multiple interconnected leadframes. Thus, the method 200 is applicable to bulk or individual fabrication processes.

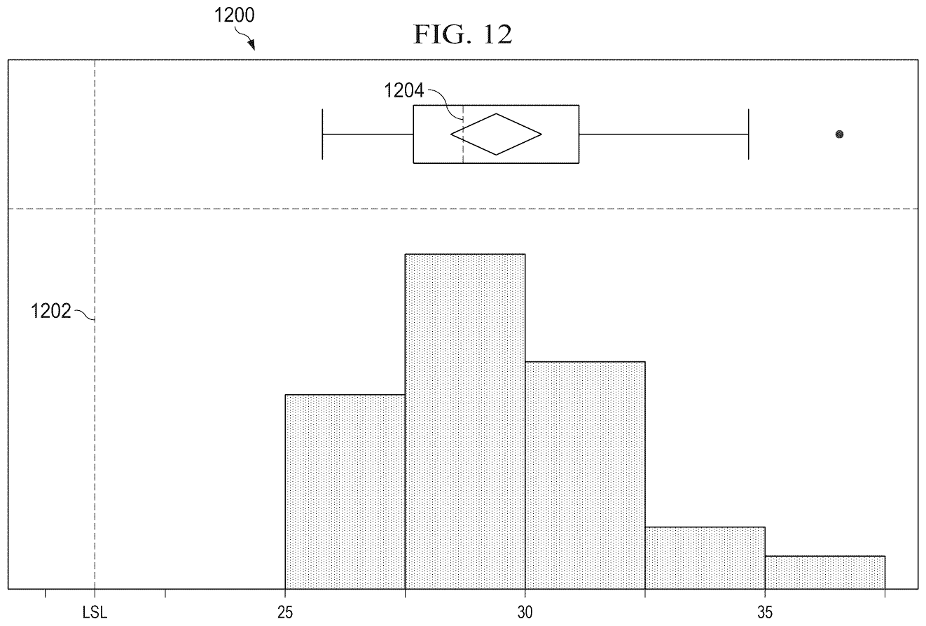

FIG. 12 illustrates a bar chart 1200 that plots a shear strength in grams-force per wire (gf/wire) for a plurality of samples of nanotwin copper pads formed through electroplating (e.g., with a solution of 32 g/L or 55 g/L). One (1) gf/wire is equal to about 0.00980665 Newtons (N). In the example illustrated, an LSL (lower spec limit) 1202 represents a minimum allowable shear strength of about 23 gf/wire. The LSL 1202 is the same minimum shear strength for a bond pad that is formed with nickel (Ni) and palladium (Pd). As illustrated, the samples of nanotwin copper pads have a shear strength of about 25 gf/wire to about 35 gf/wire, and a mean of about 29.505 gf/wire, as indicated by a line 1204. Thus, the sample nanotwin copper pads provide a shear strength that is above the LSL 1202 without the additional costs associated with nickel (Ni) and palladium (Pd) bond pads.

In this description, numerical designations “first”, “second”, etc. are not necessarily consistent with same designations in the claims herein and these numerical designations are used to simply distinguish one element from another.

Additionally, the term “couple” or variants thereof may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A. In this description, the term “based on”means based at least in part on.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Unless otherwise stated, “about,” “approximately,” or “substantially” preceding a value means within +/−10 percent of the stated value, or, if the value is zero, a reasonable range of values around zero.

Modifications are possible in the described embodiments, and other embodiments are possible, within the scope of the claims.

What is claimed is:

1. A method for fabricating an integrated circuit (IC) device, the method comprising:
forming a mask on a surface of a multi-layer substrate, in which the multi-layer substrate includes at least one leadframe having spaced apart regions of copper distributed across and extending from the surface into at least one layer of the multi-layer substrate;
forming nanotwin copper bond pads on the surface of the multi-layer substrate over a respective region of the regions of copper;
removing the mask; and
forming a layer of an insulating material over the surface of the multi-layer substrate and around the nanotwin copper bond pad.

2. The method of claim 1, further comprising planarizing the insulating material and the nanotwin copper bond pads.

3. The method of claim 1, further comprising:
mounting a die on the leadframe of the multi-layer substrate; and
attaching a copper bond wire to the nanotwin copper bond pad to provide a copper-to-copper bond between the bond wire and the nanotwin copper bond pad; and
applying a mold compound over the die, the bond wire, and at least a portion of the multi-layer substrate.

4. The method of claim 1, wherein removing the mask provides a columnar nanotwin copper bond pad extending outwardly a distance from the surface of the multi-layer substrate to define a thickness of the nanotwin copper bond pad.

5. The method of claim 4, wherein the respective region of copper has an outer periphery extending into the surface of the multi-layer substrate that is surrounded by a layer of the insulating material within the multi-layer substrate, and the columnar nanotwin copper bond pad has an outer periphery that is spaced outwardly beyond the outer periphery of the respective region of copper and extends over the insulating material adjacent the respective region of copper on the surface the surface of the multi-layer substrate.

6. The method of claim 5, wherein the insulating material comprises at least one of a build-up film material, a prepreg material, or an epoxy material.

7. The method of claim 1, wherein the nanotwin copper bond pad has a grain that includes a crystal lattice structure that has Miller indices of 111.

8. The method of claim 1, wherein electroplating comprises a pulsed plating process in which a pulsed current is applied to the multi-layer substrate immersed in a plating solution.

9. The method of claim 8,
wherein the plating solution has a copper concentration of about 30 grams per liter to about 60 grams per liter, and/or
wherein the pulsed current has a duty cycle of about 25%.

10. An apparatus, comprising:
a multi-layer leadframe comprising:
a first layer comprising:
spaced apart regions of electrically conductive material, defining respective vias, distributed across and extending from a first surface of the first layer of the leadframe into at least the first layer of the leadframe; and
a first volume of an insulating material surrounding each of the respective terminals in the at least first layer of the leadframe;
a second layer over the first surface of the first layer, the second layer comprising:
a nanotwin copper bond pad coupled to a respective one of the terminals and extending outwardly from the first surface of the first layer to terminate in a second surface of the leadframe; and
a second volume of the insulating material surrounding the nanotwin copper bond pad in the second layer of the leadframe.

11. The apparatus of claim 10, wherein:
the respective one of the vias has an outer periphery at the first surface of the leadframe that is surrounded by the insulating material, and
the nanotwin copper bond pad has a columnar sidewall having an outer periphery that is spaced outwardly in a direction orthogonal to the columnar sidewall beyond an outer periphery of the respective via and extends over the insulating material of the first layer adjacent the respective one of the vias on the first surface of the leadframe.

12. The apparatus of claim 11, wherein the second surface of the leadframe, including along the nanotwin copper bond pad and the second volume of the insulating material of the second layer, are substantially planar.

13. The apparatus of claim 11, further comprising:
an integrated circuit die on a die pad of leadframe, in which the die comprises an electrically conductive bond pad; and
a copper bond wire coupled between the nanotwin copper bond pad and the electrically conductive bond pad of the die, in which a copper-to-copper bond exists between the bond wire and the nanotwin copper bond pad; and
a mold compound over the die, the bond wire, and at least a portion of the leadframe.

14. The apparatus of claim 13, wherein the leadframe further comprises a plurality of nanotwin copper bond pads, each of the nanotwin copper bond pads is coupled to a respective one of the vias, and each of the nanotwin copper bond pads is surrounded by the second volume of the insulating material in the second layer of the leadframe.

15. The apparatus of claim 11, wherein the insulating material in each of the first and second layers comprises at least one of a build-up film material, a prepreg material, or an epoxy material.

16. The apparatus of claim 10, wherein the nanotwin copper bond pad includes a copper grain having a crystal lattice structure that has Miller indices of 111.

17. A packaged integrated circuit device, comprising:
a multi-layer substrate that comprises:
a first layer comprising a die pad and a plurality of nanotwin copper bond pads arranged and distributed about the die pad in the first layer of the multi-layer substrate, in which each of the nanotwin copper bond pads has sidewalls surrounded by an electrically insulating material in the first layer of the multilayer substrate; and
a second layer comprising a plurality of spaced apart regions of electrically conductive material, defining respective terminals, are distributed across the second layer of the multi-layer substrate, in which each of the respective terminals is coupled to a respective nanotwin copper bond pad, and each of the respective terminals extends into and is surrounded by an insulating material in the second layer of the multi-layer substrate;
a die on a surface of the die pad, in which the die includes a plurality of die bond pads on the surface thereof that is spaced apart from the surface of the die pad;
bond wires coupled between each of the die bond pads and respective nanotwin copper bond pads; and
mold compound over the die, the bond wires and at least a portion of the multi-layer substrate.

18. The packaged integrated circuit device of claim 17, wherein the nanotwin copper bond pad includes a copper grain having a crystal lattice structure that has Miller indices of 111.

19. The packaged integrated circuit device of claim 17, wherein the insulating material in each of the first and second layers of the multi-layer substrate comprises at least one of a build-up film material, a prepreg material, or an epoxy material.

20. The packaged integrated circuit device of claim 17, wherein each of the respective terminals has an outer periphery at a juncture between the first and second layers that is surrounded by the insulating material, and
the sidewall of each of the nanotwin copper bond pads has an outer periphery that extends beyond the outer periphery of the respective terminal to which it is coupled and over an adjacent portion of the insulating material of the second layer.
